(19) United States
(12) Patent Application Publication
(10) Pub. No.: US 2008/0003758 A1
(43) Pub. Date: Jan. 3, 2008

(54) VARACTOR STRUCTURE AND METHOD FOR FABRICATING THE SAME

(76) Inventor: Ching-Hung Kao, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/854,540

(22) Filed: Sep. 12, 2007

Related U.S. Application Data
(62) Division of application No. 11/160,851, filed on Jul. 12, 2005.

(51) Int. Cl. H01L 21/328

(52) U.S. Cl. 438/379; 257/E21.35

(57) ABSTRACT

A varactor structure with high quality factor and good linearity, and a method for fabricating the same are disclosed. According to the method, an additional ion implantation is performed between a first electrode ion implantation and a second electrode ion implantation to form a high doped region. In other words, a high doped region of the same conductive type as the second electrode is disposed between the second electrode and the substrate. The varactor with additional high doped region not only has a high quality factor and good linearity, but also a high tuning ratio.

### CROSS REFERENCE TO RELATED APPLICATIONS

This application is a division of U.S. application Ser. No. 11/160,851 filed Jul. 12, 2005, and incorporated herein by reference in its entirety.

### BACKGROUND OF THE INVENTION

1. Field of the Invention

The present invention is related to a varactor structure and a method for making the same, particularly to a varactor structure with a high quality factor and a good linearity and a method for making the same.

2. Description of the Prior Art

In the modern information industry, all kinds of data, information, video, and so on are all transmitted electronically; therefore, a processing circuit for dealing with electronic signals becomes one of the most important foundations of modern information business. An oscillator is an indispensable circuit block for modern digital circuits. For example, in common information systems (such as a personal computer), a global clock is required to coordinate all digital circuits in the system, so an oscillator for generating clock is required. In addition, to synchronize circuits with different clocks, phase loop lock (PLL) circuits are needed, and a precise voltage-controlled oscillator (VCO) is essential for the PLL to generate different frequencies of signals. In VCOs, the frequency of an oscillator is controlled by an applied current or voltage. Furthermore, in some precise filters, resistor-capacitor (RC) filters, in which the filter frequency can be adjusted, are utilized frequently.

However, with the filter characteristic of an RC filter and the oscillation characteristic of an inductance-capacitor (LC) oscillator, it is possible to adjust each of them by modifying the capacitance value. In devices with those characteristics, capacitors with variable capacitances, which are varactor structures, are used. The capacitance of a varactor structure, when within its operating parameters, decreases as a voltage applied to the device (the control voltage) increases. Numerous varactor structures have been developed and are employed in integrated circuit technologies. Among them, PN junction varactor structures and metal oxide semiconductor (MOS) varactor structures are commonly used.

Both the PN junction varactor structure and the MOS varactor structure designs are subject to a few general considerations: high unit capacitance, broad tuning range, high linearity within the operation parameter, and high quality factor (Q factor). The unit capacitance is defined as charge stored per unit area per unit voltage, and the tuning range is defined as the ratio ((Cₘₐₓ−Cₘᵢₙ)/Cₘᵢₙ) of the difference between the maximum unit capacitance (Cₘₐₓ) and the minimum unit capacitance (Cₘᵢₙ) to the minimum unit capacitance (Cₘᵢₙ). The linearity means the linearity of the relation between the operation voltage and the capacitance of the varactor. The Q factor is related to the resistance of a device, and degrades with the increasing of the resistance of the device. However, designing and manufacturing varactor structures in which all the considerations have been optimized remains problematic.

For example, reverse-biased PN junction varactor structures exhibit better Q factor. But their tuning ratios are limited, which are generally about 30%. For the reverse-biased PN junction varactor with critical dimension of 0.15 μm, the tuning ratio may smaller than 20%. Though the accumulation mode MOS varactor structures show large tuning ratios, their capacitances change dramatically in a small voltage range. This means that the frequency from the VCO would have significant differences when the control voltage applied on the MOS varactor structure changes a little. In addition, the accumulation mode MOS varactor structure exhibits a low Q factor. Therefore, even though the MOS varactor has a higher tuning ratio, it does not meet the requirements perfectly.

Therefore, a varactor structure with both a better Q factor and a broad tuning range is needed to meet the requirements of the modern industry.

### SUMMARY OF THE INVENTION

A varactor structure and a method for fabricating the same are disclosed according to the present invention. The present varactor structure has a higher Q factor and better linearity.

According to the claims, a substrate is provided firstly. The substrate has an ion well of a first conductive type, and a plurality of isolation structures around the ion well of the first conductive type. A gate structure is then formed on the surface of the substrate upon the ion well of the first conductive type, to serve as a first electrode of the varactor structure. Following that, an ion implantation of a first concentration is performed on the surface of the substrate to form two high doped regions of the first conductive type. Dopants in the high doped regions will diffuse to the substrate under the gate structure after a thermal process. Even more, dopants may diffuse so far that the two high doped regions may contact and form a joined high doped region. A spacer structure is then formed on both sides of the gate structure. Lastly, an ion implantation of a second concentration is performed on the surface of the substrate, to form two electrode doped regions of the first conductive type, to serve as second electrodes of the varactor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate one embodiment of the method for fabricating a varactor structure according to the present invention;

FIGS. 4-7 illustrate one embodiment of the method for fabricating a varactor structure according to the present invention;

FIG. 8 illustrates the capacitance-voltage graph of the present varactor structure;

FIG. 9 illustrates the Q factor of conventional varactor structure and the Q factor of the present varactor structure; and

FIG. 10 illustrates the leakage currents of the present varactor structure under different operation voltages.

### DETAILED DESCRIPTION

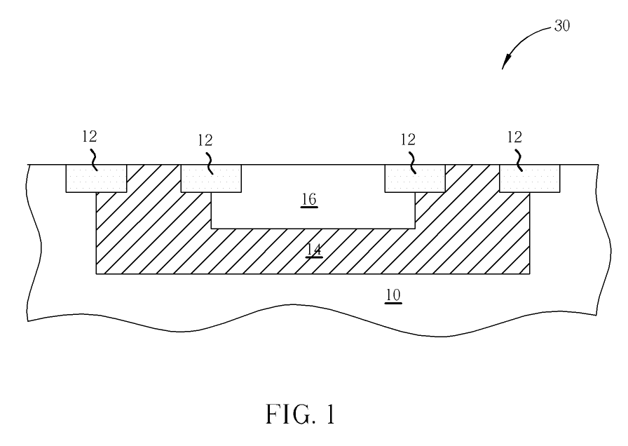

Please refer to FIGS. 1-3. FIGS. 1-3 illustrate an embodiment of the method for fabricating a varactor structure 30 according to the present invention. Please refer to FIG. 1 firstly. FIG. 1 illustrates a substrate 10 for forming the varactor structure 30 according to the present invention. The substrate 10 has a plurality of isolation structures 12, an N type deep ion well 14, and a P type ion well 16. The isolation structures 12 may be shallow trench isolation structures. However, according to the present invention, the substrate 10 may have other structures. For example, the substrate 10 may be an N type substrate. In this case, the N type deep ion well 14 is omitted, and only the P type ion well 14 is formed in the substrate. In addition, the isolation structures 12 can be formed after the ion wells 14, 16 are formed, or can be formed before the ion wells 14, 16 are formed.

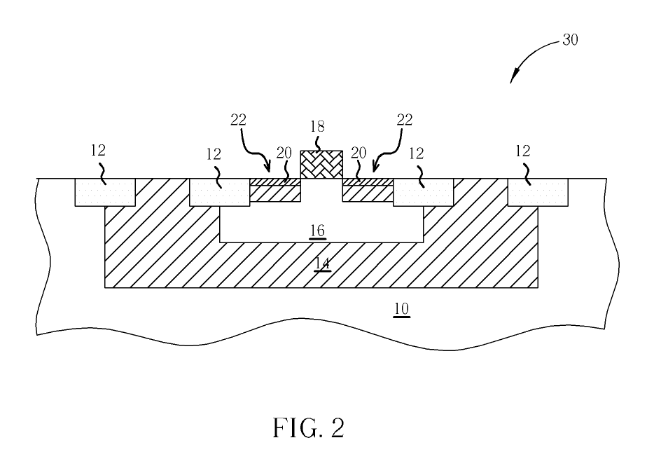

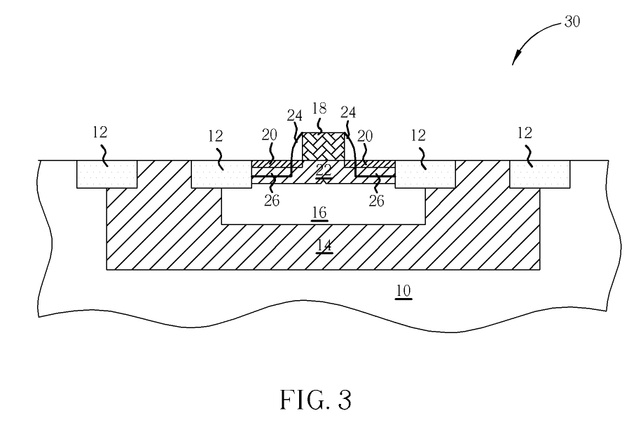

Please refer to FIG. 2. As shown in FIG. 2, a gate structure 18 is formed upon said P type ion well 16 to serve as a first electrode of the varactor structure 30. A low concentration ion implantation is performed on the surface of the substrate 10 to form two P type light doped regions 20 in the P type ion well 16 under both sides of the gate structure 18 respectively. Following that, a high concentration ion implantation is performed on the surface of the substrate 10, to form two P type high doped regions 22 in the P type ion well 16 under both sides of the gate structure respectively. Please refer to FIG. 3. After a thermal process, two P type high doped regions 22 will diffuse to the substrate under the gate structure 18. Even more, the two high doped regions 22 may contact each other and formed a joined doped region 22. A spacer structure 24 is then formed outside the gate structure 18. Another ion implantation is performed on the surface of the substrate 10 to form two P type electrode doped regions 26 in the high doped regions 22 respectively for serving as second electrodes of the varactor structure 30. It is noteworthy that both the doping concentration of the high doped regions 22 and the doping concentration of the electrode doped regions 26 are higher than the doping concentration of the P type light doped regions 20. Compared to the conventional method, an additional high concentration ion implantation is provided according to the method according to the present invention, so as to improve the characteristics, such as the Q factor and linearity, of the varactor structure 30.

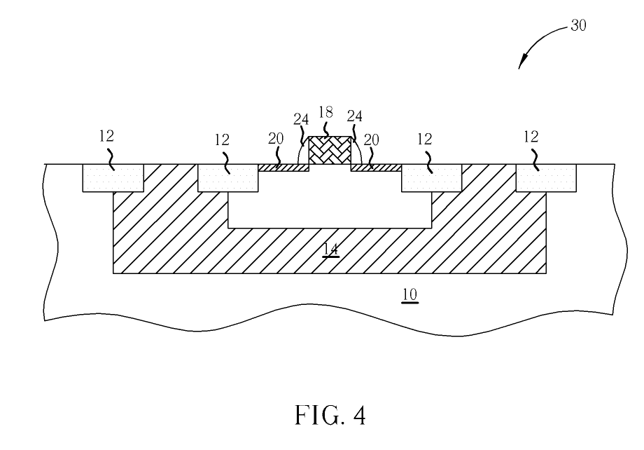

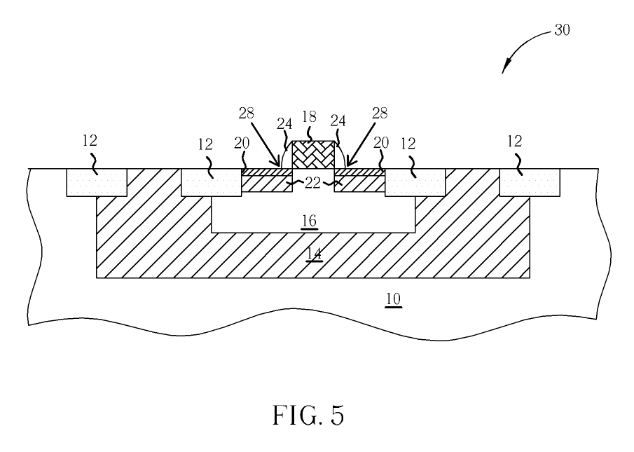

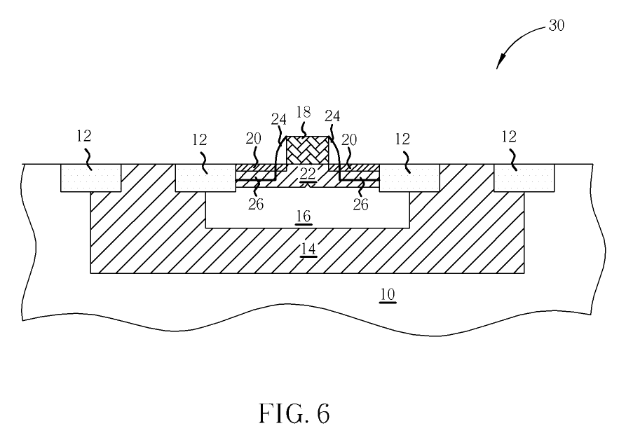

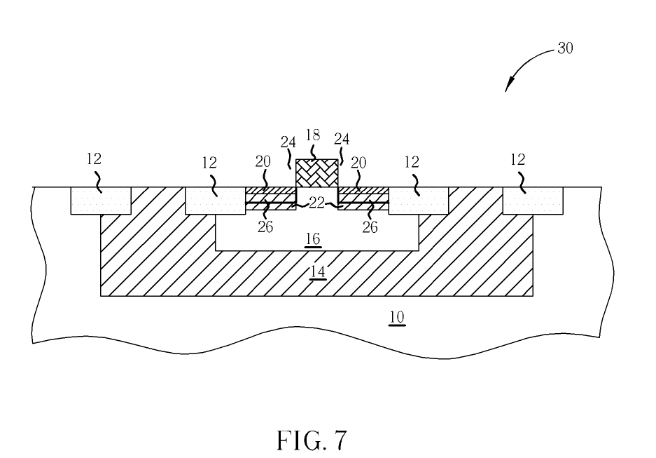

Please refer to FIGS. 4-6. FIGS. 4-6 illustrate another embodiment of the method for fabricating a varactor structure according to the present invention. As shown in FIG. 4, after the gate structure 18 is formed on the substrate 10, a low concentration ion implantation is performed on the surface of the substrate 10, to form two P type light doped regions 20 in the P type ion well 16 under both sides of the gate structure 18 respectively. A spacer structure 24 is then formed outside the gate structure 18. Following that, as shown in FIG. 5, a tilt ion implantation is performed on the surface of the substrate 10 from where the spacer structure 24 contacts the substrate 10, to form two P type high doped regions 22. A thermal process is performed to drive in the ions in the P type high doped regions 22. Lastly, as shown in FIG. 6, an ion implantation is performed on the surface of the substrate 10 to form two P type electrode doped regions 26 in the high doped regions 22 respectively for serving as second electrodes of the varactor structure 30. It is noteworthy that both the doping concentration of the high doped regions 22 and the doping concentration of the electrode doped regions 26 are higher than the doping concentration of the P type light doped regions 20. Since two P type high doped regions 22 are tilt implanted, the two P type high doped regions 22 are closer than the two electrode doped regions 26. Sometimes, the two P type regions 22 may contact each other as shown in FIG. 6. However, the present invention is not limited to this, and as shown in FIG. 7, the P type high doped regions also may not contact each other. In addition, the spacer structure 24 may be omitted according to the requirements of the process.

As shown in FIG. 3, FIG. 6 and FIG. 7, the varactor structure 30 of the present invention is different from the conventional varactor structure. An additional high concentration ion implantation is adopted in the present invention. Thus the high doped regions 22, which may contact each other due to diffusion or be separate as first, are additionally formed. However, the high doped regions 22 may be an intact region around the gate structure 18 at first rather than two regions that may contact or remain separate later. The high doped regions 22 can help to improve the Q factor and the linearity of the varactor structure 30.

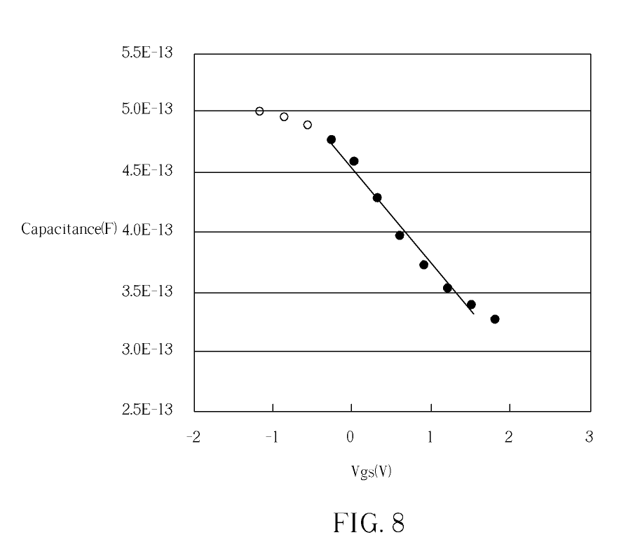

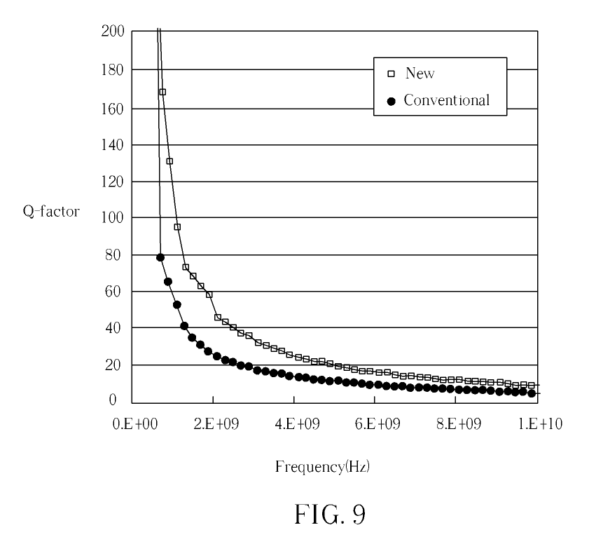

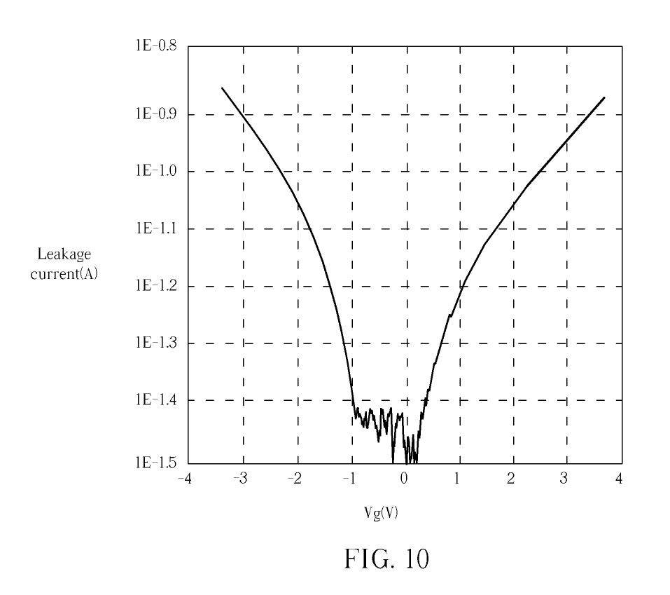

Please refer to FIG. 8. As shown in FIG. 8, when operated in the −1 V to 1.5 V voltage range, which is the operation range, the present varactor structure has a linear C-V curve without being parallel to other capacitors. In addition, the tuning ratio of the present invention is up to 46%, which is high enough for most applications. FIG. 9 illustrates the Q factor of a conventional varactor structure and the Q factor of the present varactor structure. The varactor structures have similar capacitances. The capacitance of the conventional varactor structure is 400 fF, and the capacitance of the present varactor structure is 450 fF. However, the Q factor of the present varactor structure is almost two times the Q factor of the conventional varactor structure. In other words, the present varactor structure has better performance than the conventional varactor structure. Furthermore, according to FIG. 10, the leakage currents of the present varactor structure are smaller than 10 pA within the operation range. In other words, the present invention is quite suitable for a variety of applications.

It should be noted that, the two high doped regions 22 may also be N type high doped regions. In this case, the deep ion well is P type, and the ion well 16 is N type. Similarly, when the two high doped regions 22 are N type, the substrate 10 may be a P type substrate. In this case, the deep ion well 14 is therefore omitted, and only the N type ion well 16 is formed in the substrate 10. In addition, since the high doped regions 22 will lay over the light doped regions 20, the ion concentration of the light doped regions 20 cannot maintain a low concentration. However, even without a low ion concentration region, the present invention can still perform well. This means that the light doped regions 20 are dispensable. Therefore, the process for forming the light doped regions 20 can be omitted optionally.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a varactor structure, comprising:
(a) providing a substrate having an ion well of a first conductive type, and a plurality of isolation structures disposed around the ion well of the first conductive type;
(b) forming a gate structure on the substrate upon the ion well of the first conductive type;
(c) performing an ion implantation of a first concentration on the surface of the substrate to form at least one high doped region of the first conductive type in the ion well of the first conductive type; and
(d) performing an ion implantation of a second concentration to form at least one electrode doped region of the first conductive type in the high doped region of the first conductive type.

2. The method of claim 1, wherein the substrate is a substrate of a second conductive type.

3. The method of claim 1, wherein the substrate further comprises a deep ion well of a second conductive type disposed in the substrate and around the ion well of the first conductive type.

4. The method of claim 1 further comprising performing an ion implantation of a third concentration on the substrate after step (b) to form at least one light doped region of the first conductive type in the ion well of the first conductive type.

5. The method of claim 4, wherein the third concentration is lower than the first concentration and is lower than the second concentration.

6. The method of claim 1 further comprising forming a spacer structure outside the gate structure after step (c).

7. The method of claim 1 further comprising forming a spacer structure outside the gate structure after step (b), wherein step (c) is a tilt ion implantation.

8. The method of claim 1 further comprising a thermal process.
